(19) United States
(12) Patent Application Publication
(10) Pub. No.: US 2008/0191715 A1
(43) Pub. Date: Aug. 14, 2008

(54) Solid state navigation device

(76) Inventors: Richard R. Schediwy, Santa Clara, CA (US); Shawn P. Day, Santa Clara, CA (US)

Correspondence Address: SYNAPTICS C/O WAGNER BLECHER LLP, 123 WESTRIDGE DRIVE, WATSONVILLE, CA, 95076, US

(21) Appl. No.: 11/706,896

(22) Filed: Feb. 13, 2007

(51) Int. Cl. G01R 27/26

(52) U.S. Cl. 324/663

(57) ABSTRACT

A solid state navigation device comprises a solid state dielectric nub with an upper surface configured for being contacted by an object. The upper surface comprises an intervening dielectric layer. A plurality of conductor electrodes is disposed beneath at least a portion of the intervening dielectric layer. The plurality of conductor electrodes is configured to sense a change in capacitance coupling of the plurality of conductor electrodes to the object. The change in capacitance is caused by the object contacting and moving about the upper surface.

### BACKGROUND

Conventional electronic and computing devices require a user to navigate or input a choice or selection in a number of ways. For example, a user can use an alphanumeric keyboard communicatively connected to the computing device to indicate a choice or selection. Additionally, a user can use a cursor control device communicatively connected to the computing device to indicate a choice. Also, a user can use a microphone communicatively connected to the computing device to audibly indicate a particular selection. Moreover, touch sensing technology can be used to provide an input selection to a computing device or other type of electronic device. In the field of touch sensing technology, there exist several touch sensors which are used for navigation and other input to electronic and computing devices.

One type of touch sensing navigation device is the flat touch pad which allows one dimensional or two dimensional navigation through the sensing of the capacitance of an object, such as a finger, which moves across the flat surface of the touch pad. This type of technology works well, but suffers from dimensional constraints. That is, a touch sensitive pad becomes difficult or unwieldy to use for navigation purposes when the size of the touch sensitive pad is reduced to a small area. Additionally, small electronic and computing devices, such as cellular phones often do not have sufficient surface real estate for implementing a touch sensitive pad of a practical size which will allow easy operation.

Another type of touch sensing navigation device is the touch sensitive pointing stick which senses the force of contact of an object, and then translates this force into a navigation signal. The translation can be accomplished in a variety of ways, such as, for example, the use of moveable capacitive plates coupled to the pointing stick or the use of strain gauges coupled to the pointing stick. This pointing stick technology works well in many applications, but suffers from several drawbacks. One drawback is the increased time and difficulty of manufacture that is presented due to assembly requirements and the number of parts involved. Yet another drawback is that the number and arrangement of parts, especially moving parts, makes it difficult, if not impossible to reduce the form factor of the touch sensitive pointing stick for use with very small electronic computers and devices. This is because small electronic and computing devices, such as cellular phones, often do not have enough internal volume to accommodate the parts required to implement a touch sensitive pointing stick. An additional drawback is that, due to the nature of the moving parts and construction of pointing sticks, it is difficult or impossible to seal pointing sticks against the incursion of moisture or debris.

Thus, a navigation device that addresses one or more of the above-mentioned issues would be advantageous.

### SUMMARY

A solid state navigation device comprises a solid state dielectric nub with an upper surface configured for being contacted by an object. The upper surface comprises an intervening dielectric layer. A plurality of conductor electrodes is disposed beneath at least a portion of the intervening dielectric layer. The plurality of conductor electrodes is configured to sense a change in capacitance coupling of the plurality of conductor electrodes to the object. The change in capacitance is caused by the object contacting and moving about the upper surface.

### BRIEF DESCRIPTION OF THE DRAWINGS

FIGS. 1A, 1B and 1C are exploded sectional profile views of example solid state navigation devices, according to various embodiments.

FIG. 2 is a plan view block diagram of an example solid state navigation device according to one embodiment.

FIGS. 3A-3D are detail plan views of example conductor electrode arrangements according to various embodiments.

FIG. 4 is a block diagram of an example controller for a solid state navigation device, according to an embodiment.

FIG. 5 shows a contacting object in contact with an example solid state navigation device, according to an embodiment.

FIGS. 6A-6E are exploded perspective views showing a variety of example arrangements of a protruding nub of a solid state navigation device, according to various embodiments.

FIG. 7 is a flow diagram of a method of contact based navigation that can be implemented utilizing an embodiment of the present solid state navigation device.

FIG. 8 is a flow diagram of another method of contact based navigation that can be implemented utilizing an embodiment of the present solid state navigation device.

The drawings referred to in this description should not be understood as being drawn to scale except if specifically noted.

### DETAILED DESCRIPTION

Reference will now be made in detail to embodiments of the presented technology, examples of which are illustrated in the accompanying drawings. While the presented technology will be described in conjunction with embodiments, it will be understood that they are not intended to limit the presented technology to these embodiments. On the contrary, the presented technology is intended to cover alternatives, modifications and equivalents, which may be included within the spirit and scope of the presented technology as defined by the appended claims. Furthermore, in the following detailed description, numerous specific details are set forth in order to provide a thorough understanding of the presented technology. However, it will be obvious to one of ordinary skill in the art that the presented technology may be practiced without these specific details. In other instances, well known methods, procedures, components, and circuits have not been described in detail as not to unnecessarily obscure aspects of the presented technology.

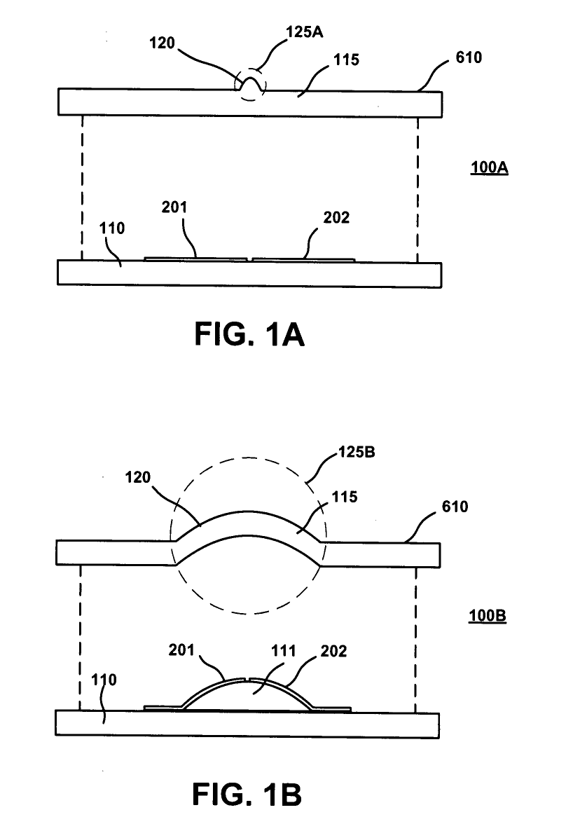

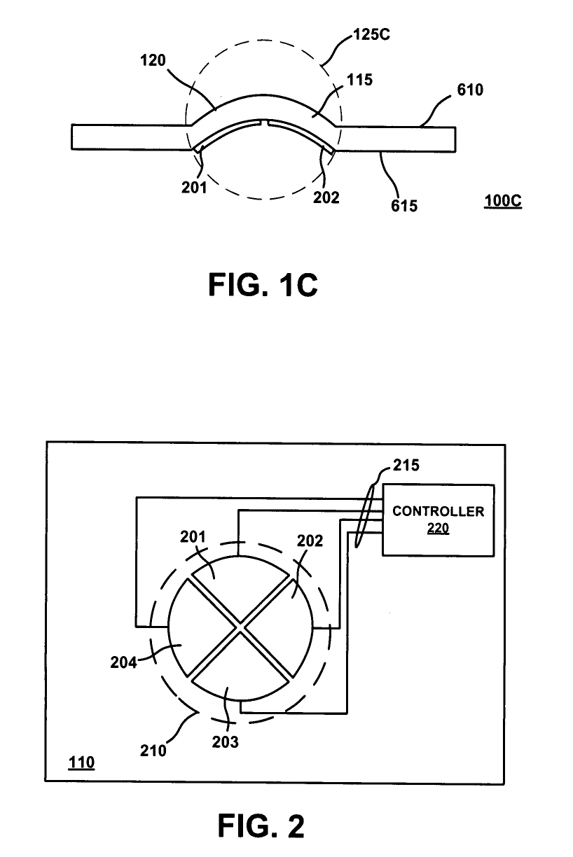

FIGS. 1A and 1B are exploded sectional profile views of example solid state navigation devices (100A and 100B), according to various embodiments. It should be appreciated that in solid state navigation devices 100A and 100B, all displayed components are stationary and that further, no moving parts are required for implementation of either device. This allows such solid state navigation devices to be manufactured in smaller form factors for use with smaller electronic devices than mechanical pointing sticks which contain moving parts.

Referring to FIG. 1A, solid state navigation device 100A is comprised of a substrate 110, which may be flexible or rigid, to which a plurality of conductor electrodes such as conductor electrodes 201 and 202 are coupled. An intervening solid state dielectric 115 is disposed above substrate 110 and configured into a nub 125A which protrudes from an otherwise substantially planar exterior surface 610. Solid state dielectric nub 125A has an upper surface 120. The solid state nature and lack of moving parts also allows solid state navigation device 100A to be easily sealed against the incursion of moisture and debris (such as through the application of a sealed dielectric layer 115 atop substrate 110). As shown in FIG. 1A, in some embodiments, a plurality of flat conductor electrodes (such as 201 and 202) are disposed beneath at least a portion of a solid state dielectric nub, such as convex solid state dielectric nub 125A.

Referring to FIG. 1B, solid state navigation device 100B is similarly comprised of a substrate 110, which may be flexible or rigid, to which a plurality of conductor electrodes such as conductor electrodes 201 and 202 are coupled. Form 111 provides a convex form to which conductor electrodes, such as conductor electrodes 201 and 202 are shaped. As shown in FIG. 1B, in some embodiments, a plurality of partially curved conductor electrodes (such as 201 and 202) are disposed beneath at least a portion of a solid state dielectric nub, such as convex solid state dielectric nub 125B. An intervening solid state dielectric 115 is disposed above substrate 110 and configured into a solid state dielectric nub 125B which protrudes from an otherwise substantially planar exterior surface 610. Solid state dielectric nub 125B has an upper surface 120. The solid state nature and lack of moving parts also allows solid state navigation device 100B to be easily sealed against the incursion of moisture and debris (such as through the application of a sealed dielectric layer 115 atop substrate 110).

In solid state navigation devices 100A and 100B like numbered components are the same, however two differences are notable. First is convex form 111, which is coupled to substrate 110 in solid state navigation device 100B. Second is the convex curvature of nub 125B which is shaped to nest above electrodes 201 and 202 and form 111, in an assembled state. In solid state navigation device 100A, intervening dielectric layer 115 of nub 125A varies in thickness above conductor electrodes 201 and 202. However, due to the nesting arrangement of nub 125B in solid state navigation device 100B, intervening dielectric layer 115 of nub 125B maintains a substantially uniform thickness above conductor electrodes 201 and 202.

Referring to FIG. 1C, solid state navigation device 100C is comprised of a solid dielectric 115, which may be flexible or rigid, to which a plurality of conductor electrodes such as conductor electrodes 201 and 202 are coupled. Dielectric 115 may have a convex solid state dielectric nub 125C. Solid state dielectric nub 125C has a convex upper surface 120 which protrudes from an otherwise substantially planar exterior surface 610. As shown in FIG. 1C, in some embodiments, a plurality of conductor electrodes (such as 201 and 202) are disposed beneath at least a portion of a solid state dielectric nub, such as convex solid state dielectric nub 125C. The conductor electrodes (such as 201 and 202 may be deposited directly upon surface 615 of solid state dielectric 115. In such an embodiment, solid state dielectric 115 provides an intervening dielectric between the conductor electrodes and upper surface 120. It is appreciated that, in an embodiment, where an interior portion of solid state dielectric nub 125C forms a concave recess in otherwise substantially planar surrounding surface 615, the plurality of electrodes (such as 201 and 202) may be partially curved, while in an embodiment where the concave recess does not exist in surface 615, the plurality of conductor electrodes (such as 201 and 202) are not curved. In FIG. 1C, solid state dielectric 115 performs the function of substrate 110 (FIGS. 1A and 1B), by providing a structure to which conductor electrodes (such as 201 and 202) may be deposited or otherwise affixed. As demonstrated, this eliminates the requirement for substrate 110. The solid state nature and lack of moving parts also allows solid state navigation device 100C to be easily sealed against the incursion of moisture and debris.

In FIGS. 1A, 1B, and 1C solid state dielectric nubs 125A, 125B, and 125C each comprise upper surface 120 which is configured for being contacted by an object for the purpose of providing an input, such as a navigation input to an electronic device. In nubs 125A, 125B, and 125C, intervening dielectric layer 115 provides for a thin insulating dielectric layer which prevents ohmic contact between conductors, such as 201 and 202, and upper surface 120. Intervening dielectric layer 115 is comprised of solid state dielectric material, as is well known in the art. For example, in some embodiments, intervening dielectric 115 comprises a molded dielectric material, such as a plastic. Likewise, in some embodiments intervening dielectric 115 comprises a printed or deposited dielectric material.

As will be seen, conductor electrodes 201 and 202 are representative of what may be a larger plurality of conductor electrodes in other embodiments. In solid state navigation devices, such as 100A, 100B, and 100C, the plurality of conductor electrodes, such as conductor electrodes 201 and 202, are disposed beneath at least a portion of intervening dielectric layer 115, and are configured to sense a change in capacitance coupling of the conductor electrodes to an object which is touching upper surface 120. The change in capacitance is caused by the object touching and moving about on upper surface 120. Any change in capacitance sensed by conductor electrodes, such as conductor electrodes 201 and 202, is coupled to a controller module 220 (FIG. 2) for conversion into a navigation signal. It is appreciated that no dedicated drive electrode is required for sensing a capacitance change caused by a contacting object contacting and/or moving about upper surface 120.

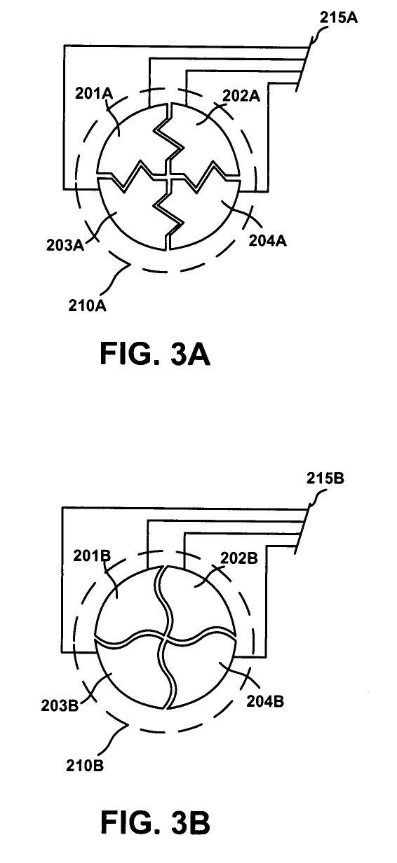

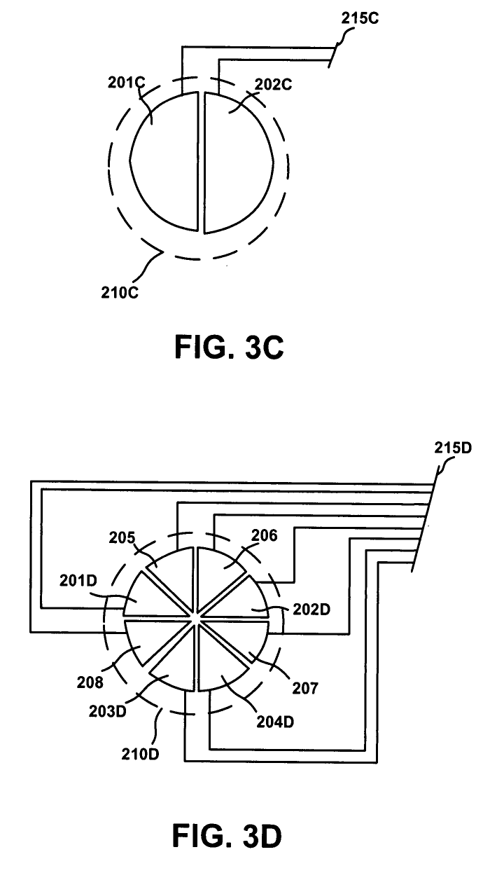

FIG. 2 is a plan view block diagram of an example solid state navigation device substrate 110 according to one embodiment. Substrate 110 comprises an arrangement of conductor electrodes 210, a set of signal lines 215, and a controller 220 (which may be located apart from substrate 110 in other embodiments). In FIG. 2 conductor electrode arrangement 210 disposes four conductor electrodes 201, 202, 203, and 204 as pie wedge quadrants upon substrate 110. Though conductor electrode arrangement 210 is shown as a circular arrangement, it may also be implemented in other shapes, such as, for example a rectangle. In other embodiments, conductor arrangement 210 may be rotated clockwise or counter-clockwise 0 to 360 degrees from the orientation shown. Additionally, it is appreciated that various alternative conductor electrode arrangements 210 are possible, some of which use more that four conductor electrodes, and some of which use fewer than four conductor electrodes. Some examples of such alternative arrangements are illustrated in FIGS. 3A-3D. It is appreciated that a conductor electrode arrangement, such as conductor electrode arrangement 210, may also be deposited or otherwise affixed to solid state dielectric 115 (as shown in FIG. 1C).

The quadrant arrangement of conductor electrodes 201, 202, 203, and 204, shown in FIG. 2, is useful for sensing capacitance changes in one or two dimensions in response to an object contacting and moving about upon upper surface 120 (FIG. 1). The use of conductor electrodes 201, 202, 203, and 204 in a quadrant type arrangement 210 allows controller 210 to translate the sensed capacitance changes into two-dimensional navigation signals. As shown by FIG. 2, the conductor electrodes, in this case conductor electrodes 201, 202, 203, and 204, are coupled to controller 220 by signal lines 215.

Controller 220 receives capacitance changes sensed by a plurality of conductor electrodes in response to an object contacting and moving about on upper surface 120 (FIG. 1). Controller 220 uses these changes in capacitance coupling of the plurality of conductor electrodes to the object for determining a navigation signal corresponding to movement of the object about the upper surface of solid state dielectric nub 125. In some embodiments, controller 220 is implemented on substrate 110 with discrete electrical components, one or more integrated circuits, one or more application specific integrated circuits (ASICs), or some combination of such circuits and/and or components. In other embodiments, signal lines 215 are coupled to a controller 220 which is implemented in either hardware or software at some location external to substrate 110.

FIGS. 3A-3D are detail plan views of example conductor electrode arrangements 210 according to various embodiments. FIGS. 3A, 3B, 3C, and 3D are shown as examples of conductor electrode arrangements 210 and are not intended to limit conductor electrode arrangement 210 to these example embodiments. For example, other conductor arrangements, such as tessellated conductor electrode arrangements, are also anticipated. In some embodiments, the conductor electrode arrangements shown in FIGS. 3A-3D may be rotated clockwise or counter-clockwise 0 to 360 degrees from the orientation shown.

In FIG. 3A, conductor electrode arrangement 210A is shown coupled to signal lines 215A. Conductor electrode arrangement 210A is comprised of a circular arrangement of four wedged shaped interlaced toothed conductor electrodes 201A, 202A, 203A, and 204A. Although shown in a circular orientation, it is appreciated that conductor electrodes 201A, 202A, 203A, and 204A may be arranged in other shapes, such as, for example, a rectangle. Conductor electrodes 201A, 202A, 203A, and 204A, are arranged substantially in quadrants, to provide for two-dimension capacitance change sensing as discussed in conjunction with FIG. 2. The interlaced toothed arrangement is one example conductor electrode arrangement 210 which may be utilized to provide increased interpolation of capacitance changes sensed by the conductor electrodes in response to an object contacting and moving about on upper surface 120 (FIG. 1).

In FIG. 3B, conductor electrode arrangement 210B is shown coupled to signal lines 215B. Conductor electrode arrangement 210B is comprised of a circular wavy arrangement of four wedged shaped conductor electrodes 201B, 202B, 203B, and 204B. Although shown in a circular orientation, it is appreciated that conductor electrodes 201B, 202B, 203B, and 204B may be arranged in other shapes, such as, for example, a rectangle. Conductor electrodes 201B, 202B, 203B, and 204B are arranged substantially in quadrants, to provide for two-dimension capacitance change sensing as discussed in conjunction with FIG. 2. The wavy arrangement is one example conductor electrode arrangement 210 which may be utilized to provide increased interpolation of capacitance changes sensed by the conductor electrodes in response to an object contacting and moving about on upper surface 120 (FIG. 1).

In FIG. 3C, conductor electrode arrangement 210C is shown coupled to signal lines 215C. Conductor electrode arrangement 210C is comprised of a circular arrangement of two hemispherical electrodes 201C and 202C. Although shown in a circular orientation, it is appreciated that conductor electrodes 201C and 202C may be arranged in other shapes, such as, for example, a rectangle. As in other embodiments, conductor electrodes 201C and 202C sense capacitance changes in response to an object contacting and moving about on upper surface 120 (FIG. 1). However, because there are only two conductor electrodes (201C, 202C) controller 220 may only determine a one-dimensional navigation signal from the changes in capacitive values received from conductor electrodes 201C and 202C.

In FIG. 3D, conductor electrode arrangement 210D is shown coupled to signal lines 215D. Conductor electrode arrangement 210D is comprised of a circular arrangement of eight wedge-shaped conductor electrodes 201D, 202D, 203D, 204D, 205, 206, 207, and 208. Although shown in a circular orientation, it is appreciated that conductor electrodes 201D, 202D, 203D, 204D, 205, 206, 207, and 208 may be arranged in other shapes, such as, for example, a rectangle. Conductor electrodes 201D, 202D, 203D, 204D, 205, 206, 207, and 208 are arranged substantially in quadrants (two conductor electrodes per quadrant), to provide for two-dimension capacitance change sensing as discussed in conjunction with FIG. 2. The eight conductor electrodes shown in arrangement 210D demonstrate one example conductor electrode arrangement 210, which may comprise more than four conductor electrodes to provide increased interpolation of capacitance changes sensed by the conductor electrodes in response to an object touching and moving about on upper surface 120 (FIG. 1). It is appreciated that more than eight conductor electrodes may be utilized, at a cost of adding some complexity to solid state navigation devices 100.

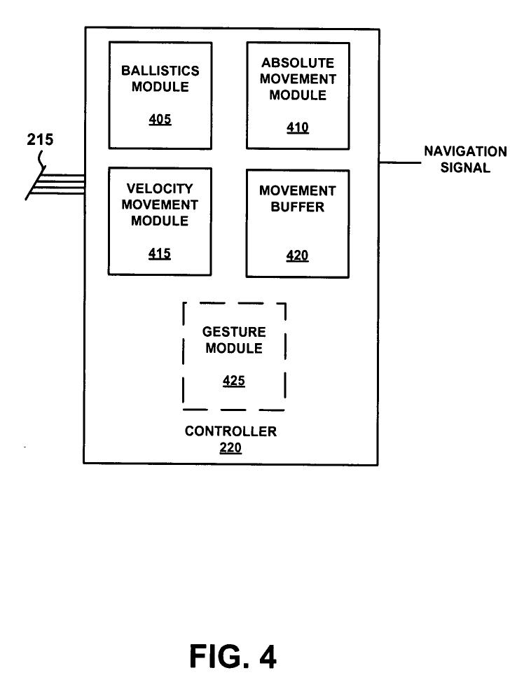

FIG. 4 is a block diagram of an example controller 220 for a solid state navigation device 100, according to an embodiment. Controller 220, in one embodiment, comprises a ballistics module 405, an absolute movement module 410, a velocity movement module 415, and a movement buffer 420. It is appreciated that in some embodiments, one or more of ballistics module 405, absolute movement module 410, velocity movement module 415, and movement buffer 420 may be omitted or combined with the functionality of another module. FIG. 4 is described in conjunction with some elements which are visible in FIG. 1A, 1B, or FIG. 2.

As shown in FIG. 4, controller 220 receives an input of sensed capacitance changes from a plurality of conductor electrodes via signal lines 215 (or signal lines 215A, 215B, 215C, or 215D). As previously described, the capacitance values that are received are the result of capacitance changes caused by an object contacting and moving about upper surface 120 (of FIG. 1A, for example). Controller 220 uses the changes in capacitance coupling of the plurality of conductor electrodes, such as conductor electrodes 210, to the object for determining a navigation signal corresponding to movement of the object about upper surface 120 of said solid state dielectric nub 125. In one embodiment, controller 220 receives a first change in capacitance value that is caused by an initial coupling between a contacting object and a plurality of conductor electrodes when the contacting object initially touches upper surface 120. The value of the first capacitive change is recorded. A second (and subsequent) change in capacitance value is received when the plurality of conductor electrodes sense a capacitance value change related to the movement of the contacting object upon upper surface 120. Controller 220 uses the recorded first capacitance value change and the second (and subsequent) capacitance value change to determine a navigation signal from the movement of the contacting object upon upper surface 120. Any subsequent capacitive changes produce a navigational signal in a similar manner, based on the recorded first capacitive change. This process continues until the contacting object no longer touches top surface 120.

In one embodiment, controller 220 includes an optional gesture module 425 which senses capacitance value changes caused by tapping a contacting object, for instance in multiple successive taps upon upper surface 120. Capacitance value changes caused by such tapping contacts may be output as a portion of the navigation signal. For example, a detection of a tapping input upon upper surface 120 is used in one embodiment to perform a menu selection on an electronic device.

In one embodiment, ballistics module 405 utilizes well known ballistics techniques to determine changes in absolute position of the navigation signal, in response to capacitance changes sensed because of the movement of an object upon upper surface 120. In one embodiment, ballistics module 405 utilizes well known ballistics techniques to determine changes in velocity of the navigation signal, in response to capacitance changes sensed due to changes in the position of the object upon the surface, possibly with increased contact pressure (which increases surface area of contact), or continued indication of movement in a particular direction by an object upon upper surface 120. Examples of such absolute position changes and velocity changes to the navigation signal are discussed in greater detail below.

In one embodiment, ballistics movement module 405 determines a dynamic zero-point associated with a location of initial contact between the object and the upper surface. This location of initial contact is determined from a first capacitance value change received from a plurality of conducting electrodes. The dynamic zero-point is the starting point from which all changes in capacitance values are measured, and thus from which changes in the navigation signal will be determined. The determination of the dynamic zero-point is reinitiated each time an object reinitiates contact with upper surface 120, and is related to the physical position of initial contact on upper surface 120. Thus in one example, a user who is performing navigation with solid state navigation device 100A, contacts upper surface 120 with a contacting object and then proceeds to move the contacting object relative to the initial contact location to perform one-dimensional or two-dimensional navigation (depending upon the configuration of solid state navigation device 100A). Through the determination of a dynamic zero-point, the point of initial contact is allowed to be anywhere on upper surface 120. Each time that the contact is initiated or reinitiated, the zero-point is dynamically associated with the initial contact point. This precludes a user from being required to initially contact solid state navigation device 100A in a specific location on upper surface 120 in order to initiate navigation input.

In one embodiment, absolute movement module 410 utilizes well known ballistics techniques to determine changes in position of the navigation signal, in response to capacitance changes sensed by a plurality of conductor electrodes due to the movement of an object upon upper surface 120. In one embodiment, absolute movement module 410 determines this positional change in the navigation signal from a second or subsequent capacitance value change received from a plurality of conducting electrodes. For example, a user who is performing navigation with solid state navigation device 100A, initially contacts any location on upper surface 120 with a contacting object and then proceeds to move the contacting object relative to the initial contact location (dynamic zero-point) to perform one-dimensional or two-dimensional navigation (depending upon the configuration of solid state navigation device 100A). In one embodiment, for example, when sensed capacitance changes due to movement indicate that small changes in position are made relative to the initial contact location by the contacting object, an absolute positioning mode is entered.

In the absolute positioning mode, absolute movement module 410 causes the navigation signal to change in a directly mapped fashion which may include ballistics with respect to movements of an object upon upper surface 120. Thus small movements cause correspondingly small navigation changes, while larger movements cause correspondingly larger navigation signal changes. As indicated previously, absolute movement module 410 may be incorporated in ballistics module 405, in one embodiment.

In one embodiment, velocity movement module 415 utilizes well known ballistics techniques to determine changes the navigation signal, in response to capacitance changes sensed by a plurality of conductor electrodes due to: changes in the position of the object upon the surface, possibly with increased contact pressure (which increases surface area of contact), or continued indication of movement in a particular direction by a contacting object upon upper surface 120. In one embodiment, velocity movement module 415 determines this positional change in the navigation signal from a second or subsequent capacitance value change received from a plurality of conducting electrodes. For example, a user who is performing navigation with solid state navigation device 100A, initially contacts any location on upper surface 120 with a contacting object and then proceeds to move the contact object relative to the initial contact location (dynamic zero-point) to perform one-dimensional or two-dimensional navigation (depending upon the configuration of solid state navigation device 100A). In one embodiment, when sensed capacitance changes indicate a larger object movement is sensed, a velocity positioning mode is entered. Likewise, in one embodiment, when sensed capacitance changes indicate that navigation is being continued in a particular direction by the contacting object for longer than a threshold period of time (such as one second), a velocity positioning mode is entered.

In the velocity positioning mode, velocity movement module 415 causes the navigation signal to change in speed with respect to movements of an object upon upper surface 120. Thus for example, a large movement causes a cursor to move across the screen of an electronic device at a very high rate of speed, especially in comparison to the speed of navigation signal change in absolute positioning mode. Similarly, when a navigation movement is being continued in a particular direction by the contacting object for longer than a threshold period, the speed of the navigation signal (such as the speed of a cursor across a display) is increased. As indicated previously, velocity movement module 415 may be incorporated in ballistics module 405, in one embodiment.

In one embodiment, movement buffer 420 determines a dynamic dead-zone surrounding an initial location of contact between the object and upper surface 120. The dynamic dead-zone allows for a small buffer area such that minute changes in the change in capacitance caused by very small movements within the dynamic dead-zone are beneath a threshold used for determining navigation signal. This allows, for example, a person with a slightly shaky hand to utilize solid state navigation device 100A without triggering unwanted navigation movements due to very slight movements of a contact object. Movement buffer 420 re-determines the location of the dynamic dead-zone each time contact with upper surface 120 is re-initiated by a contacting object. For example, in one embodiment movement buffer 420 configures the dynamic dead-zone to surround the dynamic zero-point. It is appreciated that in some embodiments, other techniques such as, for example hysteresis filtering, may be used in place of or in conjunction with movement buffer 420. It is also appreciated that in some embodiments neither movement buffer 420 nor any filtering is utilized.

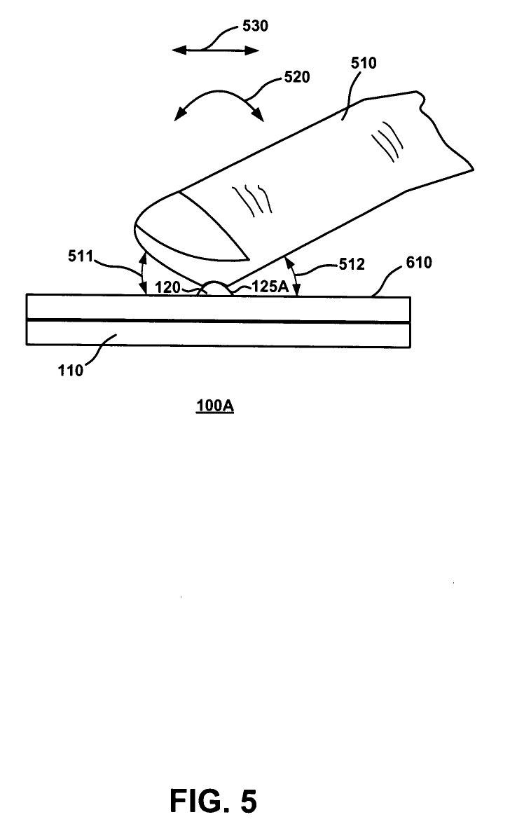

FIG. 5 shows a contacting object 510 in contact with an example solid state navigation device 100A, according to an embodiment. Solid state navigation device 100A shown in FIG. 5 is an assembled profile view of solid state navigation device 100A shown in FIG. 1A. Like numbered components visible in FIG. 5 are the same as those components shown and described in FIG. 1A.

In FIG. 5, contacting object 510 is a human finger. However, it is appreciated that although an example of a human finger is shown and described, a variety of contacting objects such as, for example: a thumb, a toe, a gloved finger, a stylus, and a writing utensil, among others, may be used with the solid state navigation devices described herein. Human finger 510 shown in FIG. 5, like a variety of other contacting objects, is sufficiently conductive and also sufficiently grounded to free space to form a measurable capacitance when placed in contact with upper surface 120 of solid state dielectric nub 125A. The capacitances measured by the conductor electrodes (such as quadrant conductor electrodes 201, 202, 203, and 204 of FIG. 2) will change with changes of the position of finger 510 on nub 125A. The capacitances measured will also change with the amount of surface area applied by finger 510.

One function of the nub shape is that air gaps are generated around the contacting object. Arrows 511 and 512 show two examples of capacitive air gaps that exist between finger 510 and upper surface 120. An object's capacitive influence on a sensor is sometimes called a “contact patch”. The contacting object creates a well defined contact patch on the nub-shaped sensor, because the air gaps around the perimeter of the contact patch are rapidly increasing. These air gaps help shape the capacitive coupling between the object and the sensor because the coupling's quicker fall off creates a more defined (or crisper edges) contact patch. The contact patch moves in a well-controlled and well-defined fashion as it follows a rolling object, such as, for example, a finger, around the nub.

Arrow 520 demonstrates a rolling movement of finger 510 upon solid state dielectric nub 125A which can be used by a user to perform navigation. The rolling motion is performed by moving finger 510, or other contact object, in a rolling or rocking manner from one contact location to another without breaking contact. The rolling motion causes finger 510 to cover more of some conductor electrode(s) disposed beneath solid state dielectric nub 125A, and less of other conductor electrode(s) disposed beneath nub solid state dielectric nub 125A. This results in corresponding changes in capacitances on the various conductor electrodes. These variations in capacitance caused by rolling motions are used by controller 220 to determine a navigation signal. For example, such a navigation signal may be used to control a cursor or to scroll through a menu on an electronic device.

Arrow 530 demonstrates a stroking movement of finger 510 upon solid state dielectric nub 125A. The stroking motion can be used by a user to perform navigation. The stroking action is similar to the movement of a finger upon a scroll wheel, except that solid state dielectric nub 125A remains stationary. This stroking motion causes finger 510, or other contact object, to cover more of some conductor electrode(s) disposed beneath solid state dielectric nub 125A, and less of other conductor electrode(s) disposed beneath solid state dielectric nub 125A. This results in corresponding changes in capacitances on the various conductor electrodes. These variations in capacitance caused by stroking motions are used by controller 220 to determine a navigation signal. For example, such a navigation signal may be used to control a cursor or to scroll through a menu on an electronic device.

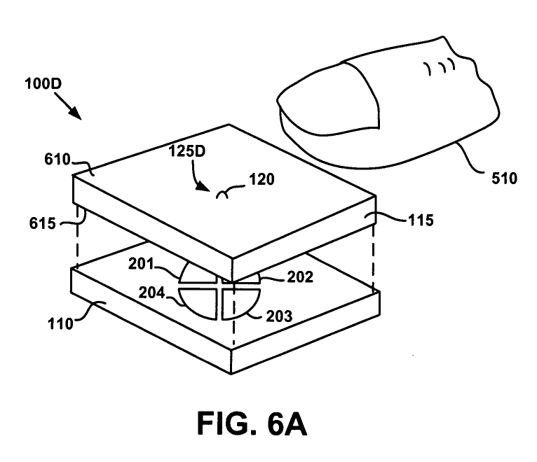

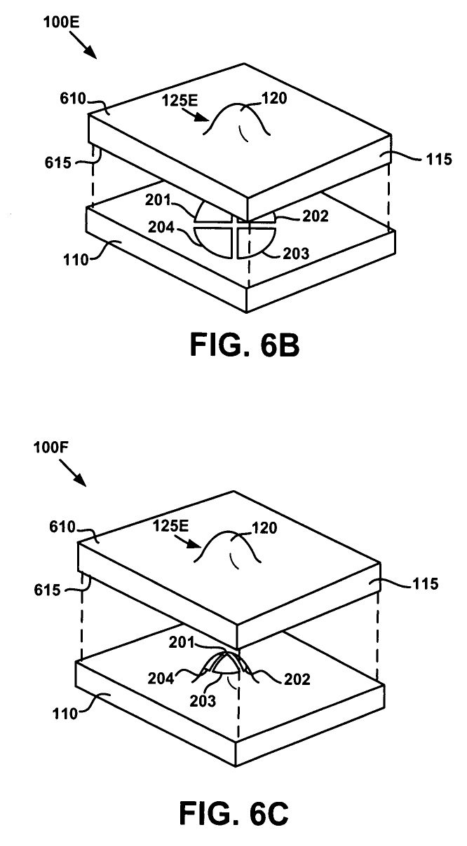

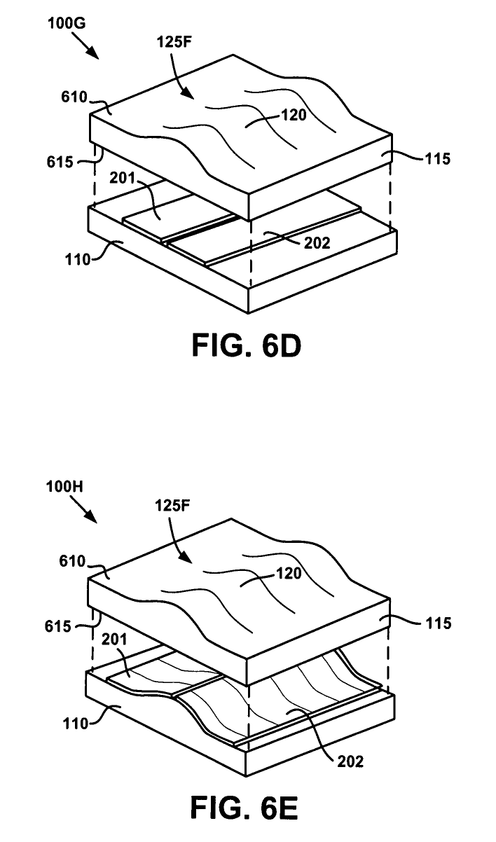

FIGS. 6A-6E are perspective views showing a variety of example arrangements of a protruding nub 125 of a solid state navigation device 100A, according to various embodiments. In FIGS. 6A-6E, like numbered elements are similar to like numbered elements in FIGS. 1A, 1B, 1C, and/or FIG. 2. Although only three example nub shapes are shown, it is appreciated that a variety of other nub shapes are anticipated within the spirit and scope of the technology described herein.

FIG. 6A shows a solid state navigation device 100D with a solid state dielectric nub 125D configured as a convex hemispherical protrusion from surface 610 of solid state dielectric 115. A finger 510 is shown moving toward surface 120 of solid state dielectric nub 125D. It is appreciated that for purposes of clarity, surface 610 and nub 125D are shown at a much larger size than is required in an actual implementation of a solid state navigation device. Solid state dielectric nub 125D may be very small, for example 1 mm in diameter, and still achieve the operational use described herein. For example, in one embodiment, solid state dielectric nub 125D is similar or equivalent in size and shape to a raised Braille dot. It is also appreciated that solid state dielectric nub 125D may be much larger, such as 15 mm in diameter. Solid state dielectric nub 125D may be configured for one-dimensional or two-dimensional navigation. Conductor electrodes 201, 202, 203, and 204 represent one embodiment of a plurality of flat conductor electrodes (similar to the arrangement shown in FIG. 2), which are disposed between surface 615 and substrate 110. In one embodiment, as described in conjunction with FIG. 1C, conductor electrodes 201-204 may be deposited upon or affixed to surface 615 of solid state dielectric 115, thus eliminating the requirement for substrate 110. In some embodiments, other conductor electrode patterns, such as, for example, those shown in FIGS. 3A-3D may be utilized.

FIG. 6B shows a solid state navigation device 100E with a solid state dielectric nub 125E configured as a cylindrical protrusion with a substantially convex upper surface 120. It is appreciated that for purposes of example, surface 610, from which solid state dielectric nub 125E protrudes, is shown at a much larger size than is required in an actual implementation of a solid state navigation device. It is appreciated that solid state dielectric nub 125E may be very small, for example 5 mm in height and a few millimeters in diameter, and still achieve the operational use described herein. It as also appreciated that solid state dielectric nub 125E may be larger in height, such as 20 mm tall, and/or larger in diameter, such as 15 mm. Solid state dielectric nub 125E may be configured for one-dimensional or two-dimensional navigation. Conductor electrodes 201, 202, 203, and 204 represent one embodiment of a plurality of flat conductor electrodes (similar to the arrangement shown in FIG. 2), which are disposed between surface 615 and substrate 110. In one embodiment, as described in conjunction with FIG. 1C, conductor electrodes 201-204 may be deposited upon or affixed to surface 615 of solid state dielectric 115, thus eliminating the requirement for substrate 110. In some embodiments, other conductor electrode patterns, such as, for example, those shown in FIGS. 3A-3D may be utilized.

FIG. 6C shows a solid state navigation device 100F with a solid state dielectric nub 125E configured as a cylindrical protrusion from surface 610. Solid state dielectric nub 125E is comprised of a substantially convex upper surface 120 (in the shape of a hemisphere). FIG. 6C is similar to FIG. 6B, except that conductor electrodes 201 (not visible), 202, 203, and 204 represent one embodiment of a plurality of curved conductor electrodes (similar to the arrangement shown in FIG. 2), which are disposed between surface 615 and substrate 110. In one embodiment, as described in conjunction with FIG. 1C, conductor electrodes 201-204 may be deposited upon or affixed to surface 615 of solid state dielectric 115, thus eliminating the requirement for substrate 110. In other embodiments, other conductor electrode patterns, such as, for example, those shown in FIGS. 3A-3D may be utilized.

FIG. 6D shows a solid state navigation device 100G with a solid state dielectric nub 125F configured as a convex hemi-cylindrical protrusion from surface 610. Solid state dielectric nub 125F has an upper surface 120. It is appreciated that for purposes of example, surface 610 is shown at a much larger size than is required in an actual implementation of a solid state navigation device. It is also appreciated that solid state dielectric nub 125F may be very small, for example 3 mm in height and a few millimeters in diameter, and still achieve the operational use described herein. It is further appreciated, that in some embodiments, solid state dielectric nub 125F is not required to extend completely across surface 610 as shown in FIG. 6C. In one embodiment, solid state dielectric nub 125F is configured for one-dimensional navigation. In one embodiment, a plurality of flat conductor electrodes, such as electrodes 201 and 202 (similar to the arrangement shown in FIG. 1A) are disposed between surface 610 and substrate 110. In one embodiment, as described in conjunction with FIG. 1C, conductor electrodes 201 and 202 may be deposited upon or affixed to surface 615 of solid state dielectric 115, thus eliminating the requirement for substrate 110.

FIG. 6E shows a solid state navigation device 100H with a solid state dielectric nub 125F configured as a convex hemi-cylindrical protrusion from surface 610. Solid state dielectric nub 125F has an upper surface 120. FIG. 6E is similar to FIG. 6D, except that conductor electrodes 201 and 202 represent one embodiment of a plurality of curved conductor electrodes (similar to the arrangement shown in FIG. 1B), which are disposed between surface 615 and substrate 110. In one embodiment, as described in conjunction with FIG. 1C, conductor electrodes 201 and 202 may be deposited upon or affixed to surface 615 of solid state dielectric 115, thus eliminating the requirement for substrate 110.

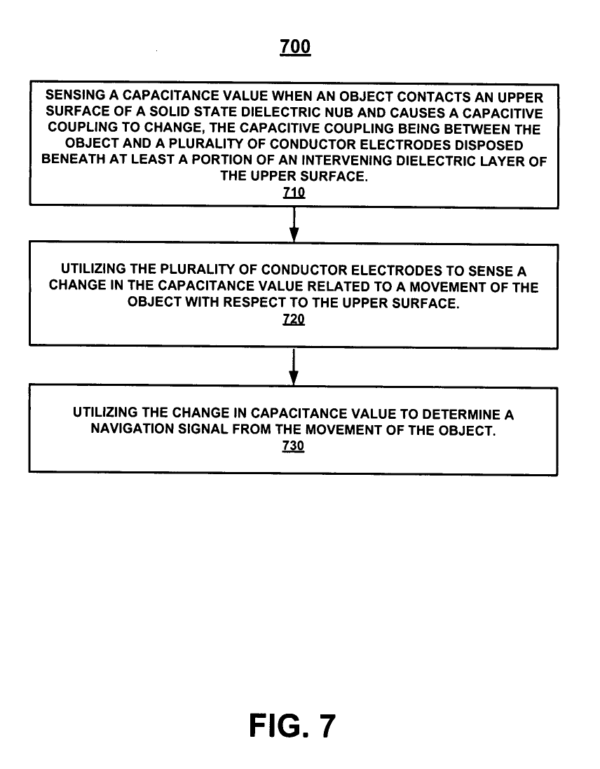

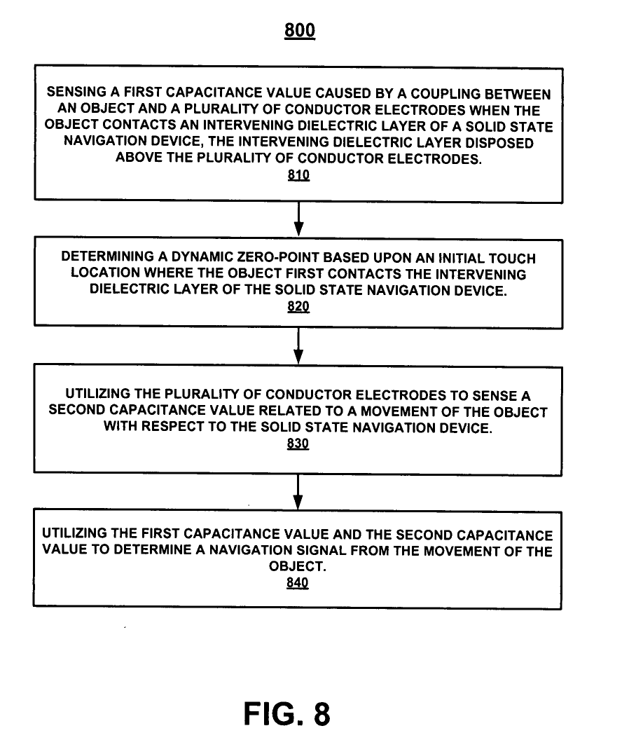

FIG. 7 and FIG. 8 are flow diagrams of examples of methods of contact based navigation that can be implemented utilizing one or more embodiments of the present solid state navigation device. Although specific steps are disclosed in flow diagrams 700 and 800, such steps are exemplary. That is, the embodiments of the present technology are well-suited to performing various other steps or variations of the steps recited in flow diagrams 700 and 800. It is appreciated that the steps in flow diagrams 700 and 800 may be performed in an order different than presented and that the steps in flow diagrams 700 and 800 are not necessarily performed in the sequence illustrated.

With reference to FIG. 7, in 710, in one embodiment, a capacitance value is sensed when an object contacts an upper surface of a solid state dielectric nub and causes a capacitive coupling to change. The capacitive coupling is a coupling between the object and a plurality of conductor electrodes, such as four conductor electrodes, disposed beneath at least a portion of an intervening dielectric layer of the upper surface. In one embodiment, this comprises sensing a change in capacitance due to a rolling movement of the object upon the upper surface. In one embodiment, this comprises sensing a change in capacitance due to a stroking movement of the object upon the upper surface. FIGS. 1A, 1B, 1C, 2, 5, and 6A-6E illustrate examples of such a solid state navigation device. Additionally, FIG. 5 illustrates directions of movement associated with an example rolling movement and an example stroking movement of a contacting object upon an intervening dielectric layer.

In 720, in one embodiment, the plurality of conductor electrodes is utilized to sense a change in the capacitance value related to a movement of the object with respect to the upper surface. FIGS. 1A, 1B, 1C, 2, and 3A-3D provide example of such pluralities of conductor electrodes which are utilized to sense the change in capacitance value, according to various embodiments.

In 730, in one embodiment, the change in capacitance value is utilized to determine a navigation signal from the movement of the object. Controller 220 determines the navigation signal from the change in capacitance value, according to one embodiment. In one embodiment, step 730 also comprises utilizing a ballistics technique to determine the navigation signal. According to various embodiments, ballistics module 405 uses ballistic techniques to determine the navigation signal. In one embodiment, at step 730, the method also determines a velocity based position change in the navigation signal. Velocity movement module 415 determines a velocity based position change in the navigation signal, according to various embodiments. In one embodiment, at step 730, the method also determines an absolute position change in the navigation signal. Absolute movement module 410 determines an absolute position change in the navigation signal, according to various embodiments.

In one embodiment, the method illustrated by flow diagram 700 also determines a dynamic zero-point corresponding to an initial contact location where the object first contacts the upper surface. Such a dynamic zero-point is determined by ballistics module 405, according to one embodiment.

Moreover, in one embodiment, the method illustrated by flow diagram 700 also configures a dead-zone surrounding an initial location of contact between the object and the upper surface. Such a dead zone is determined and configured by movement buffer 420, according to one embodiment.

With reference to FIG. 8, in 810, in one embodiment, the method senses a first capacitance value caused by a coupling between an object and a plurality of conductor electrodes when the object contacts an intervening dielectric layer of a solid state navigation device. The intervening dielectric layer is disposed above the plurality of conductor electrodes. A portion of the intervening dielectric layer comprises a protruding nub shaped surface configured for receiving the contact. In one embodiment, the contacting object comprises a finger. In one embodiment, the plurality of conducting electrodes comprises, at most, eight conducting electrodes. FIGS. 1A, 1B, and 1C demonstrate embodiments of such an intervening dielectric layer which is configured into a nub shape with an upper surface for receiving contact by a contacting object. FIGS. 5 and 6A-6C demonstrate example shapes of such a nub shaped surface along with an example contacting object in the form of a finger.

In 820, in one embodiment, the method determines a dynamic zero-point based upon an initial touch location where the contacting object first contacts the intervening dielectric layer of the solid state navigation device. Ballistics module 405 determines a dynamic zero-point based upon an initial touch location of an upper surface of an intervening dielectric layer, according to one embodiment.

In 830, in one embodiment, the method utilizes the plurality of conductor electrodes to sense a second capacitance value related to a movement of the object with respect to the solid state navigation device. FIGS. 1A, 1B, 1C, 2, and 3A-3D demonstrate a variety of arrangements of a plurality of conductor electrodes which may be used to sense a capacitance value related to a movement of a contacting object on the upper surface of a solid state dielectric nub, according to various embodiments. In one embodiment, step 830 comprises utilizing the plurality of conductor electrodes to sense a second capacitance value related to a rolling motion performed on the intervening dielectric layer by the object. In one embodiment, step 830 comprises utilizing the plurality of conductor electrodes to sense a second capacitance value related to a stroking and/or rolling motion performed on the intervening dielectric layer by the object. FIGS. 1A, 1B, 1C, 2, 5, and 6A-6E illustrate examples of such a solid state navigation device. Additionally, FIG. 5 illustrates directions of movement associated with an example rolling movement and an example stroking movement of a contacting object upon an intervening dielectric layer.

In 840, in one embodiment, the first capacitance value and the second capacitance value are utilized to determine a navigation signal from the movement of the object. Controller 220 is utilized to determine a navigation signal from a first capacitance value and a second capacitance value, according to one embodiment. In one embodiment, step 840 also comprises determining a velocity based position change in the navigation signal. In various embodiments, the determination of a velocity based position change is performed by ballistics module 405 and/or velocity movement module 415. In one embodiment, step 840 also comprises determining an absolute position change in the navigation signal. In various embodiments, the determination of an absolute position change in the navigation signal is performed by ballistics module 405 and/or absolute movement module 410.

The foregoing descriptions of specific embodiments have been presented for purposes of illustration and description. They are not intended to be exhaustive or to limit the presented technology to the precise forms disclosed, and obviously many modifications and variations are possible in light of the above teaching. The embodiments were chosen and described in order to best explain the principles of the presented technology and its practical application, to thereby enable others skilled in the art to best utilize the presented technology and various embodiments with various modifications as are suited to the particular use contemplated. It is intended that the scope of the embodiments of the present technology be defined by the claims appended hereto and their equivalents.

What is claimed is:

1. A solid state navigation device comprising:
a solid state dielectric nub with an upper surface configured for being contacted by an object, said upper surface comprising an intervening dielectric layer; and
a plurality of conductor electrodes disposed beneath at least a portion of said intervening dielectric layer, said plurality of conductor electrodes configured to sense a change in capacitance coupling of said plurality of conductor electrodes to said object, said change in capacitance caused by said object contacting and moving about said upper surface.

2. The device of claim 1, further comprising:
a controller configured to use said change in capacitance coupling of said plurality of conductor electrodes to said object for determining a navigation signal corresponding to movement of said object about said upper surface of said solid state dielectric nub.

3. The device of claim 2, wherein said controller further comprises:
a ballistics module configured for determining a dynamic zero-point associated with a location of initial contact between said object and said upper surface.

4. The device of claim 2, wherein said controller further comprises:
an absolute movement module configured for determining a change in said navigation signal in response to said change in capacitance coupling said plurality of conductor electrodes to said object.

5. The device of claim 2, wherein said controller further comprises:
an velocity movement module configured for determining a change in said navigation signal in response to said change in capacitance coupling said plurality of conductor electrodes to said object.

6. The device of claim 2, wherein said controller further comprises:
a movement buffer configured for determining a dynamic dead-zone surrounding an initial location of contact between said object and said upper surface such that minute changes in said change in capacitance are beneath a threshold used for determining said navigation signal.

7. The device of claim 2, wherein said controller further comprises:
a gesture module configured for determining a change in said navigation signal in response to said change in capacitance coupling said plurality of conductor electrodes to said object.

8. The device of claim 1, wherein said plurality of conductor electrodes comprises no more than four conductor electrodes.

9. The device of claim 1, wherein said object comprises a finger.

10. The device of claim 1, wherein said solid state dielectric nub comprises a convex shape.

11. The device of claim 10, wherein said solid state dielectric nub comprises a hemi-cylindrical shape.

12. The device of claim 10, wherein said solid state dielectric nub comprises a hemispherical shape.

13. The device of claim 10, wherein the plurality of conductor electrodes disposed beneath at least a portion of said solid state dielectric nub are flat.

14. The device of claim 1, wherein said solid state navigation device does not require a dedicated drive electrode.

15. A method of contact based navigation, said method comprising:
sensing a capacitance value when an object contacts an upper surface of a solid state dielectric nub and causes a capacitive coupling to change, said capacitive coupling being between said object and a plurality of conductor electrodes disposed beneath at least a portion of an intervening dielectric layer of said upper surface;
utilizing said plurality of conductor electrodes to sense a change in said capacitance value related to a movement of said object with respect to said upper surface; and
utilizing said change in capacitance value to determine a navigation signal from said movement of said object.

16. The method as recited in claim 15, further comprising:
determining a dynamic zero-point corresponding to an initial contact location where said object first contacts said upper surface.

17. The method as recited in claim 15, further comprising:
configuring a dead-zone surrounding an initial location of contact between said object and said upper surface.

18. The method as recited in claim 15, wherein said utilizing said change in capacitance value to determine a navigation signal from said movement of said object comprises:
utilizing a ballistics technique to determine said navigation signal.

19. The method as recited in claim 15, wherein said utilizing said change in capacitance value to determine a navigation signal from said movement of said object comprises:
determining a velocity-based position change in said navigation.

20. The method as recited in claim 15, wherein said utilizing said change in capacitance value to determine a navigation signal from said movement of said object comprises:
determining an absolute position change in said navigation signal.

21. The method as recited in claim 15, wherein said utilizing said plurality of conductor electrodes to sense a change in said capacitance value related to a movement of said object with respect to said upper surface comprises:
sensing a change in capacitance due to a rolling movement of said object upon said upper surface.

22. The method as recited in claim 15, wherein said utilizing said plurality of conductor electrodes to sense a change in said capacitance value related to a movement of said object with respect to said upper surface comprises:
sensing a change in capacitance due to a stroking movement of said object upon said upper surface.

23. The method as recited in claim 15, wherein said plurality of conductor electrodes comprises four conductor electrodes.

24. A method of contact based navigation:
sensing a first capacitance value caused by a coupling between an object and a plurality of conductor electrodes when said object contacts an intervening dielectric layer of a solid state navigation device, said intervening dielectric layer disposed above said plurality of conductor electrodes;
determining a dynamic zero-point based upon an initial touch location where said object first contacts said intervening dielectric layer of said solid state navigation device;
utilizing said plurality of conductor electrodes to sense a second capacitance value related to a movement of said object with respect to said solid state navigation device; and
utilizing said first capacitance value and said second capacitance value to determine a navigation signal from said movement of said object.

25. The method as recited in claim 24, wherein a portion of said intervening dielectric layer comprises a protruding nub shaped surface configured for receiving said contact.

26. The method as recited in claim 24, wherein said object comprises a finger.

27. The method as recited in claim 24, wherein said utilizing said first capacitance value and said second capacitance value to determine a navigation signal from said movement of said object comprises:
determining a velocity-based position change in said navigation signal.

28. The method as recited in claim 24, wherein said utilizing said first capacitance value and said second capacitance value to determine a navigation signal from said movement of said object comprises:
determining an absolute position change in said navigation signal.

29. The method as recited in claim 24, wherein said utilizing said plurality of conductor electrodes to sense a second capacitance value related to a movement of said object with respect to said solid state navigation device:
utilizing said plurality of conductor electrodes to sense a second capacitance value related to a rolling motion performed on said intervening dielectric layer by said object.

30. The method as recited in claim 24, wherein said utilizing said plurality of conductor electrodes to sense a second capacitance value related to a movement of said object with respect to said solid state navigation device:
utilizing said plurality of conductor electrodes to sense a second capacitance value related to a stroking motion performed on said intervening dielectric layer by said object.

31. The method as recited in claim 24, wherein said plurality of conductor electrodes comprises at most eight conducting electrodes.
